(19) United States
(12) Patent Application Publication
(10) Pub. No.: US 2022/0158060 A1
(43) Pub. Date: May 19, 2022

(54) DISPLAY PANEL AND DISPLAY DEVICE

(71) Applicant: KunShan Go-Visionox Opto-Electronics Co., Ltd., Kunshan (CN)

(72) Inventors: Yu JIN, Kunshan (CN); Enlai WANG, Kunshan (CN); Rulong LI, Kunshan (CN); Wangfeng XI, Kunshan (CN); Jijun JIANG, Kunshan (CN); Nan SHEN, Kunshan (CN)

(73) Assignee: KunShan Go-Visionox Opto-Electronics Co., Ltd., Kunshan (CN)

(21) Appl. No.: 17/588,729

(22) Filed: Jan. 31, 2022

Related U.S. Application Data
(63) Continuation of application No. PCT/CN2021/070159, filed on Jan. 4, 2021.

(30) Foreign Application Priority Data
Feb. 26, 2020 (CN) 202010121624.4

(51) Int. Cl. H01L 33/62; H01L 33/38; H01L 27/15; H01L 33/10; H01L 33/42

(52) U.S. Cl. CPC H01L 33/62; H01L 33/382; H01L 33/42; H01L 33/10; H01L 27/156

(57) ABSTRACT

A display panel and a display device. The display panel includes a transition region, a light-transmitting region, and a driving backboard. The driving backboard includes: a first driving circuit located in the transition region, the first driving circuit having a first output end; a first planarization layer located on the driving backboard of the transition region and the light-transmitting region; a first electrode layer located at a side of the first planarization layer of the transition region; a second planarization layer located at a side of the first planarization layer and the first electrode layer; a second electrode layer located at a side of the second planarization layer of the transition region and the light-transmitting region, and the second electrode layer extending through the second planarization layer to contact with the first electrode layer.

### CROSS REFERENCE TO RELATED APPLICATIONS

The present application is a continuation of PCT application No. PCT/CN2021/070159, filed on Jan. 4, 2021, the PCT application claims the priority of Chinese patent application No. 202010121624.4 entitled “Display Panel, Method for Manufacturing the same, and Display Device”, filed on Feb. 26, 2020. Each of which is incorporated by reference herein in its entirety.

### TECHNICAL FIELD

The embodiments of the present disclosure relate to the field of display technology, and in particular to a display panel and a display device.

### BACKGROUND

In addition to display screens, terminal equipment such as mobile phones and tablet computers usually has functional devices like cameras, fingerprint recognition chips, speakers, and earpieces. As terminal equipment continues to become intelligent and mobile, the functions of terminal equipment continue to be enriched, and its built-in functional devices are also increasing.

In order to increase the screen-to-body ratio of the terminal equipment, a display panel using the full-screen technology emerges. However, the performance of the existing display panel still needs to be improved.

### SUMMARY

Some embodiments of the present disclosure provide a display panel and a display device, so as to improve the display performance of the display panel.

In order to solve the above problems, some embodiments of the present disclosure provide a display panel. The display panel includes a transition region and a light-transmitting region, a light transmittance of the light-transmitting region is greater than a light transmittance of the transition region. The display panel includes:
a driving backboard including a first driving circuit in the transition region, and the first driving circuit having a first output end;
a first planarization layer, located on the driving backboard of the transition region and the light-transmitting region;
a first electrode layer, located at a side of the first planarization layer of the transition region, the side of the first planarization layer of the transition region being away from the driving backboard, and the first electrode layer extending through the first planarization layer to electrically connect with the first output end;
a second planarization layer, located at a side of the first planarization layer and the first electrode layer, the side of the first planarization layer and the first electrode layer being away from the driving backboard;
a second electrode layer, located at a side of the second planarization layer of the transition region and the light-transmitting region, the side of the second planarization layer of the transition region and the light-transmitting region being away from the driving backboard, and the second electrode layer extending through the second planarization layer to contact with the first electrode layer.

Some embodiments of the present disclosure also provide a display device, including the display panel.

### BRIEF DESCRIPTION OF THE DRAWINGS

FIG. 1 is a cross-sectional schematic diagram of a display panel according to an embodiment of the present disclosure.

FIG. 2 is a top view of a first electrode layer of the display panel in FIG. 1.

FIG. 3 is a top view of a second electrode layer, a transition region electrode, and a main screen region electrode of the display panel in FIG. 1.

FIG. 4 is a cross-sectional schematic diagram of a display panel according to another embodiment of the present disclosure.

FIG. 5 is a top view of a first electrode layer, a third electrode layer and a fifth electrode layer of the display panel in FIG. 4.

FIG. 6 is a top view of a second electrode layer, a fourth electrode layer, and a sixth electrode layer of the display panel in FIG. 4.

FIG. 7 is a structural schematic diagram corresponding steps of the method for manufacturing the display panel according to an embodiment of the present disclosure.

FIG. 8 is a structural schematic diagram corresponding steps of the method for manufacturing the display panel according to an embodiment of the present disclosure.

FIG. 9 is a structural schematic diagram corresponding steps of the method for manufacturing the display panel according to an embodiment of the present disclosure.

FIG. 10 is a structural schematic diagram corresponding steps of the method for manufacturing the display panel according to an embodiment of the present disclosure.

FIG. 11 is a structural schematic diagram corresponding steps of the method for manufacturing the display panel according to an embodiment of the present disclosure.

### DETAILED DESCRIPTION

It can be known from the background that the performance of the existing display panel needs to be improved. In order to increase a light transmittance of a light-transmitting region and improve lighting effect of lighting components (such as the camera) in the light-transmitting region, usually no driving circuit is provided on a driving backboard of the light-transmitting region. A light-emitting unit in the light-transmitting region is provided with an electrical signal by the driving circuit of the transition region. However, when improving the light transmittance of the light-transmitting region, some new problems may arise, for example, abnormal overlap between the output end of the driving circuit and the anode of the main screen region and the transition region, Ag migration in the anode of the main screen region and the transition region, which may cause the abnormal display of the main screen region and the transition region.

In order to solve the above problems, some embodiments of the present disclosure provide a display panel with superior structural performance. A planarization layer and a structure for electrically connecting electrodes of first light-emitting units in the light-transmitting region are all new structures, which can improve the performance of the display panel.

In order to make the objectives, technical solutions, and advantages of the embodiments of the present disclosure clearer, the various embodiments of the present disclosure will be described in detail below with reference to the accompanying drawings. However, those skilled in the art may understand that in each embodiment of the present disclosure, many technical details are proposed to provide the reader a better understanding of the present disclosure. However, even without these technical details and various changes and modifications based on the following embodiments, the technical solution claimed in the present disclosure can be realized.

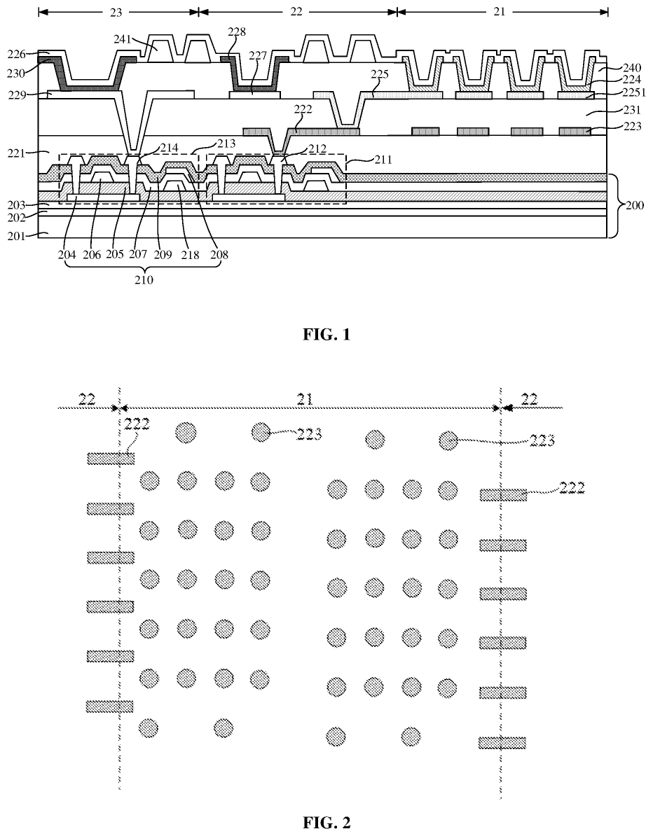

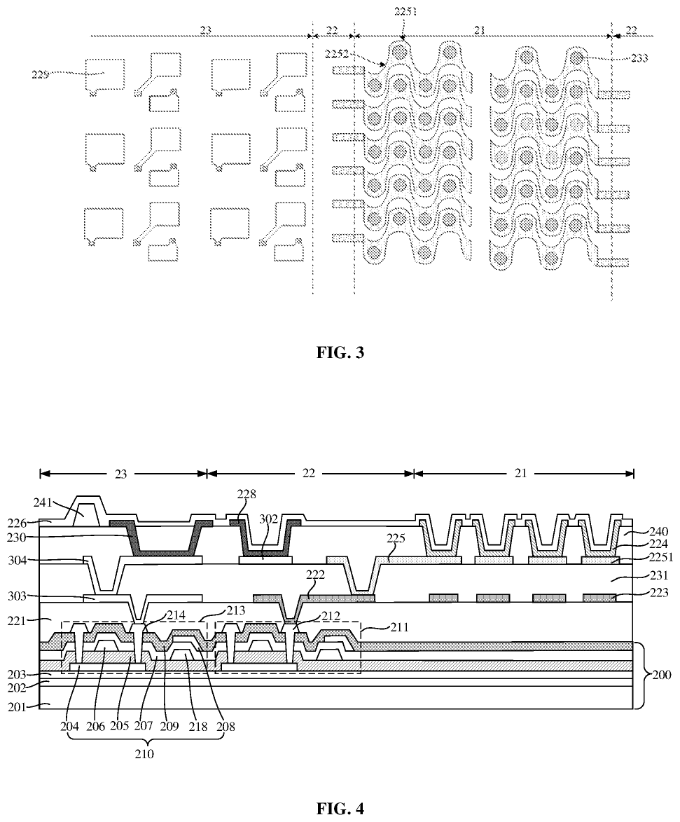

FIG. 1 to FIG. 3 are structural schematic diagrams of the display panel provided by an embodiment of the present disclosure. FIG. 1 is a cross-sectional schematic diagram of the display panel, FIG. 2 is a top view of a first electrode layer of the display panel in FIG. 1, and FIG. 3 is a top view of a second electrode layer, a transition region electrode, and a main screen region electrode of the display panel in FIG. 1. It should be noted that the main screen region is not shown in FIG. 2.

Referring to FIG. 1 to FIG. 3, in this embodiment, the display panel includes a transition region 22 and a light-transmitting region 21, and a light transmittance of the light-transmitting region 21 is greater than a light transmittance of the transition region 22. The display panel also includes: a driving backboard 200 including a first driving circuit 211 located in the transition region 22, and the first driving circuit 211 having a first output end 212; a first planarization layer 221, located on the driving backboard 200 of the transition region 22 and the light-transmitting region 21; a first electrode layer 222, located at a side of the first planarization layer 221 of the transition region 22, the side of the first planarization layer 221 of the transition region 22 being away from the driving backboard 200, and the first electrode layer 222 extending through the first planarization layer 221 to connect with the first output end 212; a second planarization layer 231, located at a side of the first planarization layer 221 and the first electrode layer 222, the side of the first planarization layer 221 and the first electrode layer 222 being away from the driving backboard 200; a second electrode layer 225, located at a side of the second planarization layer 231 of the transition region 22 and the light-transmitting region 21, the side of the second planarization layer 231 of the transition region 22 and the light-transmitting region 21 being away from the driving backboard 200, and the second electrode layer 225 extending through the second planarization layer 231 to contact with the first electrode layer 222.

The display panel provided in this embodiment will be described in detail below with reference to the accompanying drawings.

The display panel may be an OLED display panel, an LCD display panel, an LED display panel or a Micro-LED display panel. Taking the display panel as an OLED display panel as an example, the OLED display panel may be a top-emitting display panel or a bottom-emitting display panel.

In this embodiment, the transition region 22 and the light-transmitting region 21 have display functions. The difference is that the light transmittance of the light-transmitting region 21 is greater than the light transmittance of the transition region 22, so that when the lighting component is used in the display panel, the lighting components arranged in the light-transmitting region 21 have excellent lighting performance, and the display panel can still realize full-screen display. In this embodiment, the display panel further includes a main screen region 23, the transition region 22 is located between the main screen region 23 and the light-transmitting region 21. The light transmittance of the light-transmitting region 21 is greater than the light transmittance of the main screen region 21, and the light transmittance of the transition region may be the same as the light transmittance of the main screen region 23. In other embodiments, the light transmittance of the transition region may also be less than the light transmittance of the main screen region.

The driving backboard 200 includes a substrate 201 and a driving component layer 210 on the substrate 201. In this embodiment, the display panel may be applied to a flexible display device. Correspondingly, the substrate 201 is a flexible substrate and a material of the flexible substrate may be for example, polyethylene (PE), polypropylene (PP), polystyrene (PS), Polyethylene Terephthalate (PET), Polyethylene Naphthalate (PEN) or Polyimide (PI). The substrate 201 may also be an ultra-thin glass substrate, and a thickness of the ultra-thin glass substrate is less than 50 μm.

In this embodiment, the driving backboard may further include a first transition layer 202 and a second transition layer 203 which are sequentially stacked between the substrate 201 and the driving component layer 210. A material of the first transition layer 202 may be silicon nitride, and a material of the second transition layer 203 may be silicon oxide. It shall be understood that in other embodiments, the substrate may also be a rigid substrate, such as rigid glass.

The driving component layer 210 provides driving signals for the light emitting unit in the display panel to emit light. The driving component layer 210 is a multi-layer structure, specifically, including: an active layer 204; a gate structure located on the active layer 204, the gate structure includes a gate dielectric layer 205 and a gate electrode layer 206 located on the gate dielectric layer 205; a source in the active layer 204 located at one side of the gate structure 206, a drain in the active layer 204 located at the other side of the gate structure; a first capacitor conductive layer 218 located on the gate dielectric layer 205; a capacitor dielectric layer 207 covering the gate structure, the first capacitor conductive layer 218 and the gate electrode layer 206; a second capacitor conductive layer 208 located on the capacitor dielectric layer 207 and directly opposite to the first capacitor conductive layer 218 to form a storage capacitor; an insulating dielectric layer 209 covering the capacitor dielectric layer 207 and the second capacitor conductive layer 208; a source electrode and a drain electrode extending through the insulating dielectric layer 209, the capacitor dielectric layer 207 and the gate dielectric layer 205, and the source electrode being electrically connected to the source, and the drain electrode being electrically connected to the drain.

In this embodiment, the driving component layer 210 has a thin film transistor (TFT) and a storage capacitor, and the thin film transistor may be a low temperature poly-silicon (LTPS) thin film transistor. It should be understand that the driving component layer 210 may also include other film layer structures, and the above only lists the structure of the thin film transistor as an example.

The driving component layer 210 is used to form a driving circuit. The driving circuit may include at least one thin film transistor and at least one storage capacitor. The thin film transistor may be a switch tube and/or a driving tube. In this embodiment, there is no driving circuit in the driving component layer 210 of the light-transmitting region 21, so as to meet the requirement of high light transmittance of the light-transmitting region 21. In other words, the light-transmitting region 21 does not have thin film transistors and storage capacitors. The driving component layer 210 of the transition region 22 is provided with a first driving circuit 211, and the first driving circuit 211 is provided with a first output end 212. In this embodiment, the first output end 212 is a drain electrode of the thin film transistor in the first driving circuit 211.

In this embodiment, the driving backboard 200 further includes a second driving circuit (not shown) located in the transition region 22, and the second driving circuit is provided with a second output end, which is used for providing an electrical signal for the light emitting unit of the transition region 22. The driving backboard 200 may further include a third driving circuit 213 located in the main screen region 23, and the third driving circuit 213 is provided with a third output end 214. The third output end 214 may be a drain electrode of the thin film transistor in the third driving circuit to provide an electrical signal for the light-emitting units of the main screen region 23.

The first planarization layer 221 not only covers the driving backboard 200 of the light-transmitting region 21 and the transition region 22, but also covers the driving backboard 200 of the main screen region 23. On the one hand, the first planarization layer 221 may provide a surface with relatively high flatness. On the other hand, the first planarization layer 221 also provides an interface basis for the first electrode layer 222.

A material of the first planarization layer 221 is a transparent material, which specifically may be an inorganic transparent material such as silicon oxide, or an organic transparent material such as polyethylene (PE), polypropylene, polystyrene, polyethylene terephthalate, polyethylene naphthalate or polyimide. In this embodiment, the material of the first planarization layer 221 is polyimide.

The first planarization layer 221 may have a thickness of 1.2 μm ˜2.5 μm, and further, the first planarization layer 221 may have a thickness of 1.6 μm, 2 μm, or 2.3 μm.

In this embodiment, the first planarization layer 221 of the transition region 22 is provided with a first through hole (not shown) exposing the first output end 212 to provide conditions for electrically connecting the first electrode layer 222 and the first output end 212.

The first electrode layer 222 is located on a surface of the first planarization layer 221 of the transition region 22, the surface of the first planarization layer 221 of the transition region 22 is away from the driving backboard 200, and The first electrode layer 222 is also located on a sidewall of the first through hole and a surface of the first output end 212 exposed by the first through hole. In other words, at least a part of the first electrode layer 222 passes through the first through hole to contact with the surface of the first output end 212. In this embodiment, the first electrode layer 222 includes a first transparent electrode layer, a metal electrode layer, and a second transparent electrode layer which are sequentially stacked. A material of the first transparent electrode layer and the second transparent electrode layer includes ITO (Indium Tin Oxide) or IZO (Zinc Tin Oxide), and a material of the metal electrode layer includes at least one of Mg, Ag, or Al. As an example, the first electrode layer 222 may have a laminated structure of ITO layer/Ag layer/ITO layer. In other embodiments, the first electrode layer may also be a single-layer structure or a laminated structure, for example, it may be a laminated structure of an IZO layer/Ag layer/IZO layer.

The display panel further includes a plurality of first light-emitting units 224 in the light-transmitting region 21, the first light-emitting units 224 are located at a side of the second electrode layer 225, the side of the second electrode layer 225 is away from the driving backboard 200, and the second electrode layer 225 is used for providing electrical signals for the plurality of the first light emitting units 224.

In this embodiment, the display panel further includes a plurality of discrete light-reflective layers 223, the light-reflective layers 223 are located at a side of the first planarization layer 221 of the light-transmitting region 21, the side of the first planarization layer 221 of the light-transmitting region 21 is away from the driving backboard 200, and each of the light-reflective layers 223 is corresponding to a position of each of the first light-emitting units 224. The function of the light-reflecting layers 223 includes: the light-reflecting layers 223 serve as a fully light-reflective layer constituting the optical microcavity in the display panel, so that the display panel may form an optical microcavity the light-transmitting region 21. Specifically, the light-reflecting layers 223, the first light-emitting units 224, and the cathode 226 may form an optical microcavity to improve the light-emitting characteristics of the light-transmitting region 21. In addition, the arrangement of the light-reflecting layers 223 are also conducive to reducing the cavity length difference between the optical microcavity of the light-transmitting region 21 and the optical microcavity of the transition region 22, so as to improve the display uniformity of the light-transmitting region 21 and the transition region 22, and is also conducive to reducing the cavity length difference between the optical microcavity of the light-transmitting region 21 and the optical microcavity of the main screen region 23, so as to improve the display uniformity of the light-transmitting region 21 and the main screen region 23. There is an interval between the adjacent light-reflecting layers 223 of the light-transmitting region 21, which is conducive to reducing the adverse effect of the light reflecting layers 223 on the light transmittance of the light transmitting area 21, and ensuring that the light transmitting area 21 has a high light transmittance.

In this embodiment, an orthographic projection of each of the light-reflective layers 223 on the driving backboard 200 is located within an orthographic projection of each of the first light-emitting units 224 on the driving backboard 200.

In this embodiment, the light reflecting layers 223 and the first electrode layer 222 are provided in the same layer, and a material of the light reflecting layers 223 is the same as a material of the first electrode layer 222. In this way, the process steps may be reduced and the process difficulty may be decreased. That is to say, in this embodiment, the light-reflective layer 223 is a laminated structure of ITO layer/Ag layer/ITO layer. In other embodiments, the light-reflecting layer may also be a laminated structure of IZO layer/Ag layer/IZO layer.

FIG. 2 is a top view of the first electrode layer 222 of the transition region 22 and the reflective layer 223 of the light-transmitting region 21. As shown in FIG. 2, a plurality of the first electrode layers may be arranged in parallel and a shape of a surface of the reflective layer 223 away from the driving backboard 200 is circular. It should be understand that the shape of the surface of the reflective layer 223 away from the driving backboard 200 may also be square or other irregular shapes.

A material of the second planarization layer 231 is a transparent material, and specifically may be an inorganic transparent material or an organic transparent material. In this embodiment, the material of the second planarization layer 231 is the same as the material of the first planarization layer 221. In other embodiments, the materials of the second planarization layer and the first planarization layer may also be different.

The second planarization layer 231 may have a thickness of 1.2 μm ˜2.5 μm, and further, the second planarization layer 231 may have a thickness of 1.6 μm, 2 μm, or 2.3 μm.

In this embodiment, the second planarization layer 231 of the transition region 22 is provided with a second through hole (not shown) exposing the first electrode layer 222 to provide conditions for electrically connecting the second electrode layer 225 and the first electrode layer 222.

The light transmittance of the second electrode layer 225 is greater than the light transmittance of the first electrode layer 222, which helps to ensure that the light-transmitting region 21 has a high light transmittance.

In addition to the light-transmitting region 21, the second electrode layer 225 is also located on a surface of the second planarization layer 231 of the transition region 22, the surface of the second planarization layer 231 of the transition region 22 is away from the driving backboard 200, and the second electrode layer 225 is also located on a sidewall of the second through hole and a surface of the first electrode layer 222 exposed by the second through hole. In other words, at least a part of the second electrode layer 225 passes through the second through hole to contact the surface of the first electrode layer 222.

FIG. 3 is a top view of the second electrode of the transition region 22 and the second electrode of the light-transmitting region 21. The second electrode layer 225 is used for providing electrical signals for the plurality of first light-emitting units 224, and the shape of each of the second electrode layers 225 is related to the position distribution of the plurality of first light-emitting units 224, ensuring that the same second electrode layer 225 and the plurality of the first light-emitting units 224 are electrically connected, and the adjacent second electrode layers 225 are not electrically connected. It should be noted that, for the convenience of illustration and description, the light-reflective layers 223 are also shown in FIG. 3.

The second electrode layer 225 in the light-transmitting region 21 includes a plurality of electrode blocks 2251 and electrode bridges 2252 for connecting adjacent electrode blocks 2251, and each of the first light-emitting units 224 is correspondingly located at a side of each of the electrode blocks 2251, the side of each of the electrode blocks 2251 is away from the driving backboard 200.

A material of the second electrode layers 225 may be ITO or IZO. In this embodiment, the material of the second electrode layers 225 is ITO, and a thickness of the second electrode layers 225 is 300 Å˜450 Å, such as 320 Å, 360 Å, and 400 Å.

In this embodiment, the material of the second electrode layer 225 is a transparent conductive material, and the second electrode layer 225 is a single-layer structure.

Further, the number of the plurality of first light-emitting units 224 may be greater than two, and a shape of the second electrode layer 225 in the light-transmitting region 21 is a wave shape, and each of the electrode blocks 2251 is located at a peak of the wave shape or a trough of the wave shape. In this way, the pixel density of the light-transmitting region 21 may be increased. In this embodiment, the number of the first light-emitting units 224 is four, that is, the same second electrode layer 225 is electrically connected to the four first light-emitting units 224. In other embodiments, the same second electrode layer may also be electrically connected to two, three, or any number of the first light-emitting units.

Since each of the second electrode layers 225 include the electrode blocks 2251 respectively corresponding to the positions of the first light-emitting units 224 and the electrode bridge 2252 for connecting the adjacent electrode blocks 2251, the shape and position of the second electrode layer 225 may be flexibly set. For example, the shape of the second electrode layer 225 may be adjusted reasonably according to the positions of the first light-emitting units 224 electrically connected with the same second electrode layer 225 to improve the flexibility of the arrangement of the first light-emitting units 224 in the light-transmitting region 21.

The first light emitting unit 224 includes: a hole injection layer (HIL), a hole transport layer (HTL) located on the hole injection layer, and a emitting layer (EML), the electron transport layer (ETL) located on the light-emitting layer, and the electron injection layer (EIL) located on the electron transport layer.

The first light emitting unit 224 may emit red light, blue light, or filter light.

The display panel further includes: a transition region electrode 227, the transition region electrode 227 is located at a side of the second planarization layer 231 of the transition region 22, the side of the second planarization layer 231 of the transition region 22 is away from the driving backboard 200, and the transition region electrode 227 extends through the first planarization layer 221 and the second planarization layer 231 to electrically connect with the second output end; a second light-emitting unit 228 in the transition region 22, the second light-emitting unit 228 is located at a side of the transition region electrode 227, the side of the transition region electrode 227 is away from the driving backboard 200, and the transition region electrode 227 is used for providing an electrical signal for the second light-emitting unit 228. It should be noted that the second driving circuit electrically connected to the transition region electrode 227 is not shown in FIG. 2.

In this embodiment, the display panel has a third through hole extending through the second planarization layer 231 and the first planarization layer 221 in the transition region 22, and the third through hole exposes the second output end. The transition region electrode 227 is also located in a sidewall of the third through hole and a surface of the second output end exposed by the third through hole. In other words, at least a part of the transition region electrode 227 extends through the third through hole to contact the surface of the second output end. The transition region electrode 227 includes a first transition transparent electrode, a transition metal electrode, and a second transition transparent electrode which are sequentially stacked. A material of the first transition transparent electrode and the second transition transparent electrode is ITO or IZO, and a material of the transition metal electrode is Mg, Ag or Al.

The display panel further includes: a main screen region electrode 229, the main screen region electrode 229 is located at a side of the second planarization layer 231 of the main screen region 23, the side of the second planarization layer 231 of the main screen region 23 is away from the driving backboard 200, and the main screen region electrode 229 extends through the first planarization layer 221 and the second planarization layer 231 to electrically connect with the third output end 214; a third light emitting unit 230 in the main screen region 23, and the third light emitting unit 230 is located at a side of the main screen region electrode 229, the side of the main screen region electrode 229 is away from the driving backboard 200, and the main screen region electrode 229 is used for providing an electrical signal for the third light emitting unit 230.

In this embodiment, the main screen region 23 has a fourth through hole extending through the second planarization layer 231 and the first planarization layer 221, and the fourth through hole exposes the third output end 214. The main screen region electrode 229 is also located on a sidewall of the four-through hole and a surface of the third output end 214 exposed by the fourth through hole. In other words, at least a part of the main screen region electrode 229 passes through the fourth through hole to contact the surface of the third output end 214. The main screen region electrode 229 includes a first main screen transparent electrode, a main screen metal electrode, and a second main screen transparent electrode which are sequentially stacked. A material of the first main screen transparent electrode and the second main screen transparent electrode is ITO or IZO, and a material of the main screen metal electrode is Mg, Ag or Al.

In this embodiment, the display panel further includes: a pixel defining layer 240, located at a side of the second planarization layer 231, the side of the second planarization layer 231 is away from the driving backboard 200, and the pixel defining layer 240 is used to define positions of the first light emitting unit, the second light emitting unit, and the third light emitting unit; a cathode 226, covering the first light-emitting units, the second light-emitting units and the third light-emitting units; a supporting column 241, located at a side of the pixel defining layer 240, the side of the pixel defining layer 240 is away from the driving backboard 200, and the cathode 226 also covers the supporting column 241.

In this embodiment, the planarization layer includes a first planarization layer 221 and a second planarization layer 231 which are sequentially stacked. The electrode for electrically connecting the first driving circuit 211 and the first light-emitting units 224 include: a first electrode layer 222 located between the first planarization layer 221 and the second planarization layer 231, and the first electrode layer 222 is located in the transition region 22; a second electrode layer 225 located on the surface of the second planarization layer 231, and the second electrode layer 225 is located in the transition region 22 and the light-transmitting region 21, and also a light transmittance of the second electrode layer 225 is greater than a light transmittance of the first electrode layer 222. That is to say, there is no need to provide a transparent conductive material such as ITO at a side of the first planarization layer 221, the side of the first planarization layer 221 is facing to the driving backboard 200, so that the adverse effects caused by the process steps of forming ITO can be avoided. For example, the damage to the second output end 22 of the transition region and the third output end 214 of the main screen region 23 caused by the process steps of forming ITO can be avoided, thereby avoiding the problem of abnormal overlap and improving the performance of the display panel.

Specifically, only the second electrode layer 225 with high light transmittance is used as the anode of the light-transmitting region 21, so that a single layer of ITO may be used to wiring for the anode of the light-transmitting region 21, which is conducive to saving ITO production capacity.

In addition, for the light-transmitting region 21 and the transition region 22, the first electrode layer 222 is closer to the driving backboard 200 than the second electrode layer 225. More specifically, the laminated structure of the ITO layer/Ag layer/ITO layer is conducive to preventing the ITO manufacturing process from damaging the second planarization layer 231 of the transition region 22 and the main screen region 23, thereby helping to solve the Ag migration problem in the transition region 22 and the main screen region 23 from the source.

The first light-emitting unit 224 is a pixel structure. In this embodiment, the arrangement of the pixel structures in the light-transmitting region 21 is optimized, so that the pixel structure and the first driving circuit may be electrically connected through the first electrode layer 222 and the second electrode layer 225, so as to avoid the damage to the surface of the planarization layer caused by the ITO process, thereby solving the problem of abnormal Ag migration in the ITO layer/Ag layer/ITO layer caused by the ITO process from the source.

In an example, a first transparent electrode layer needs to be formed at a side of the planarization layer in the light-transmitting region, the side of the planarization layer in the light-transmitting region faces to the driving backboard, and a second transparent electrode layer needs to be formed at a side of the planarization layer in the light-transmitting region, the side of the planarization layer in the light-transmitting region is away from the driving backboard. Taking the material of the first transparent electrode layer and the second transparent electrode layer as ITO as an example, the third output end of the main screen region and the second output end of the transition region may be exposed to the process environment of sputtering ITO for two times and patterning for two times, which may cause changes in the physical and chemical properties of the materials of the surfaces of the second output end and the third output end, and the second output end and the third output end may be damaged, resulting in abnormal overlap between the second anode and the second output end and the abnormal overlap between the third anode and the third output end. In addition, the planarization layer of the transition region and the main screen region of this example may also be exposed to the sputtering process environment used to form the second transparent electrode layer, and the ITO material bombards the surface of the planarization layer, causing the performance of the surface of the planarization layer to be poor. Correspondingly, when the anodes of the main screen region and the transition region are formed on the surface of the planarization layer, Ag in the anodes of the main screen region and the transition region is easy to migrate from the damaged planarization layer surface, resulting in forming an loose and uneven layer of Ag, and also resulting in an abnormal performance of the display panel. That is to say, when manufacturing the first transparent electrode and the second transparent electrode in the existing technology, the second output end, the third output end and the surface of the planarization layer may all be bombarded by sputtering, resulting in changes in the physical and chemical properties of the surface, which in turn leads to problems of abnormal overlap and Ag migration.

Another embodiment of the present disclosure further provides a display panel. The display panel is substantially the same as the display panel provided in the previous embodiment. The main difference is that the transition region electrode and the main screen region electrode are different from the previous embodiment. The display panel provided by another embodiment of the present disclosure will be described in detail below with reference to the accompanying drawings. For the same or corresponding parts as the previous embodiment, reference may be made to the detailed description of the foregoing embodiment, which will not be repeated below.

FIG. 4 to FIG. 6 are schematic diagrams of the structure of a display panel provided by another embodiment of the present disclosure.

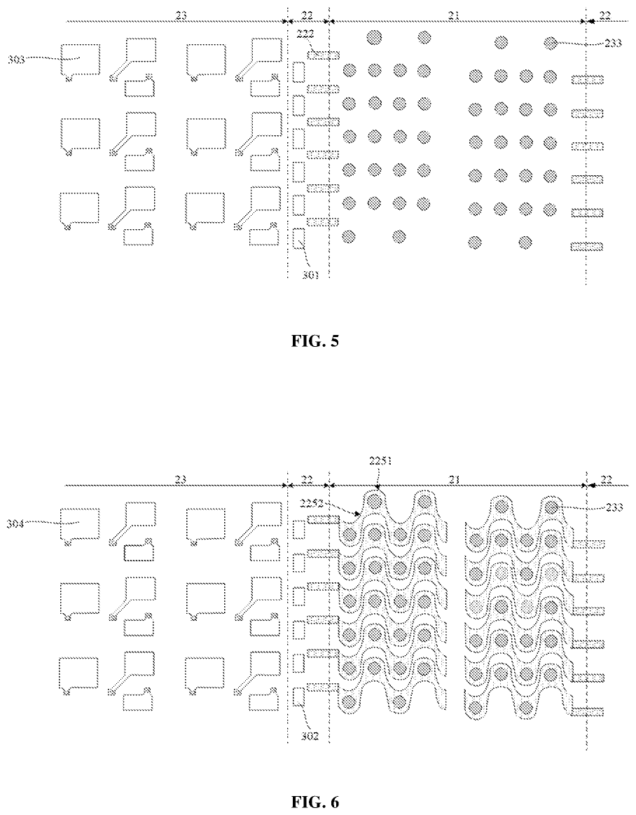

FIG. 4 is a cross-sectional schematic diagram of the display panel provided by another embodiment of the present disclosure, FIG. 5 is a top view of the first electrode layer, the third electrode layer, and the fifth electrode layer of the display panel in FIG. 4, and FIG. 6 is a top view of the second electrode layer, the fourth electrode layer, and the sixth electrode layer of the display panel in FIG. 4.

Referring to FIG. 4 and FIG. 5, the transition region electrode includes: a third electrode layer 301, the third electrode layer 301 is located at a side of the first planarization layer 221, the side of the first planarization layer 221 is away from the driving backboard 200, and the third electrode layer 301 extends through the first planarization layer 221 to connect with the second output end; a fourth electrode layer 302, the fourth electrode layer 302 is located at a side of the second planarization layer 231,the side of the second planarization layer 231 is away from the driving backboard 200, and the fourth electrode layer 302 extends through the second planarization layer 231 to contact with the third electrode layer 301.

In this embodiment, the third electrode layer 301 and the first electrode layer 222 are provided in the same layer and have the same material, and the fourth electrode layer 302 and the second electrode layer 225 are provided in the same layer and have the same material.

Referring to FIG. 4 and FIG. 6, the main screen region electrode includes: a fifth electrode layer 303, the fifth electrode layer 303 is located at a side of the first planarization layer 221, the side of the first planarization layer 221 is away from the driving backboard 200, and the fifth electrode layer 303 extends through the first planarization layer 221 to connect with the third output end 214; a sixth electrode layer 304, the sixth electrode layer 304 is located at a side of the second planarization layer 231, the side of the second planarization layer 231 is away from the driving backboard 200, and the sixth electrode layer 304 extends through the second planarization layer 231 to contact with the fifth electrode layer 303.

In this embodiment, the fifth electrode layer 303 and the first electrode layer 222 are provided in the same layer and have the same material, and the sixth electrode layer 304 and the second electrode layer 225 are provided in the same layer and have the same material.

In this way, the first electrode layer 222, the third electrode layer 301, and the fifth electrode layer 303 may be prepared in the same process step, and the second electrode layer 225, the fourth electrode layer 302, and the sixth electrode layer 304 may be prepared in the same process step, making the wiring process of the light-transmitting region 21 compatible with the wiring process of the main screen region 23 and the transition region 22, which is conducive to reducing process steps, saving process time, and reducing the manufacturing cost of the display panel.

In addition, the first electrode layer 222, the third electrode layer 301, the fifth electrode layer 303, and the light-reflecting layer 223 are provided in the same layer, in this way, it is conducive to ensuring the consistency of the cavity length of the optical microcavity in the main screen region 23, the transition region 22 and the light transmission area 21, thereby improving the display uniformity of the main screen region 23, the transition region 22 and the light transmission area 21, and further improving the display effect of the display panel.

Specifically, the first electrode layer 222, the third electrode layer 301, the fifth electrode layer 303, and the light-reflecting layer 223 each serves as a fully reflective layer constituting the optical microcavity, and the cathode 226 serves as a semitransparent and semireflective layer constituting the optical microcavity. The first electrode layer 222, the first light-emitting unit 224 and the cathode form a first optical microcavity of the light-transmitting region 21, and the third electrode layer 301, the second light-emitting unit 228 and the cathode 226 form a second optical microcavity of the transition region 22; the five electrodes 303, the third light-emitting unit 230, and the cathode 226 form a third optical microcavity of the main screen region 23. Since the fully reflective layer of each of the optical microcavity is located at the same position, and the semitransparent and semireflective layer of each of the optical microcavity is located at the same position, the cavity lengths of the first optical microcavity, the second optical microcavity, and the third optical microcavity are the same, which makes the display color purity of the light-transmitting region 21, the transition region 22 and the main screen region 23 consistent, and further improves the display effect of the display panel.

Correspondingly, some embodiments of the present disclosure also provide a display device, including the display panel in any of the foregoing embodiments. The display device may be a product or component with a TV function such as a mobile phone, a tablet computer, a TV, a displayer, a digital photo frame, or a navigator.

Further, the display device further includes a lighting component, the lighting component corresponds to the position of the light-transmitting region, and the lighting component may be a camera or a fingerprint recognition chip or the like.

Correspondingly, some embodiments of the present disclosure also provide a method for manufacturing the display panel, which may be used to manufacture the display panel in the above-mentioned embodiments. The display panel includes a transition region and a light-transmitting region which are adjacent to each other, and a light transmittance of the light-transmitting region is greater than a light transmittance of the transition region. The method includes steps of: S1, providing a driving backboard, wherein the driving backboard includes a first driving circuit located in the transition region, and the first driving circuit has a first output end; S2, forming a first planarization layer, wherein the first planarization layer is located on the driving backboard of the transition region and the light-transmitting region; S3, forming a first electrode layer, wherein the first electrode layer is located at a side of the first planarization layer of the transition region, the side of the first planarization layer of the transition region is away from the driving backboard, and the first electrode layer extends through the first planarization layer to electrically connect to the first output end; S4, forming a second planarization layer, wherein the second planarization layer is located at a side of the first planarization layer and the first electrode layer, the side of the first planarization layer and the first electrode layer is away from the driving backboard; and S5, forming a second electrode layer, wherein the second electrode layer is located at a side of the second planarization layer of the transition region and the light-transmitting region, the side of the second planarization layer of the transition region and the light-transmitting region is away from the driving backboard, and the second electrode layer extends through the second planarization layer to contact with the first electrode layer. And the light transmittance of the second electrode layer is greater than the light transmittance of the first electrode layer.

Hereinafter, the method for manufacturing the display panel provided by an embodiment of the present disclosure will be described in detail with reference to FIG. 4 and FIG. 7 to FIG. 11.

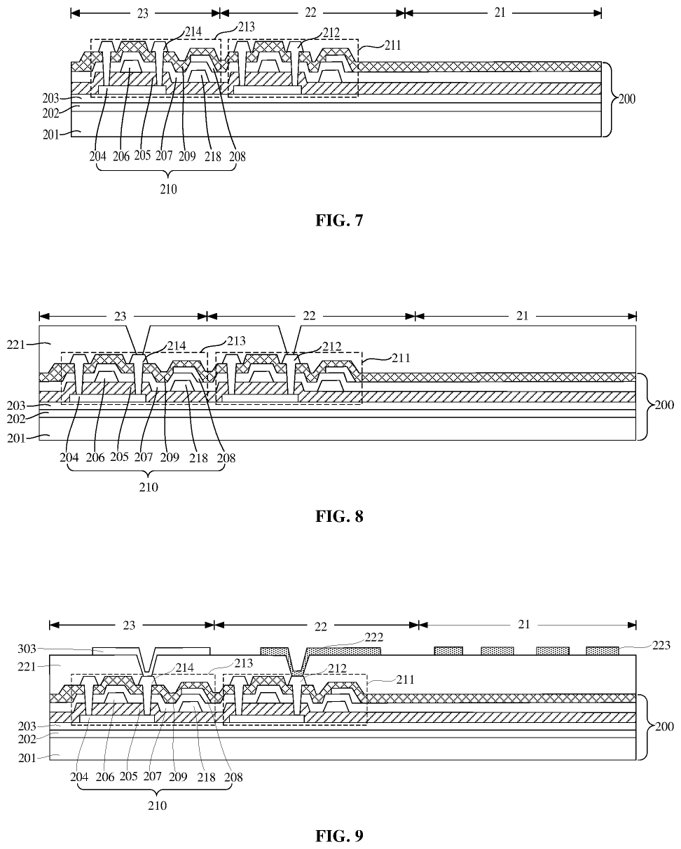

In step S1, referring to FIG. 7, a driving backboard 200 is provided. The driving backboard 200 includes a main screen region 23, a transition region 22, and a light-transmitting region 21. The transition region 22 is located between the main screen region 23 and the light-transmitting region 21. The driving backboard 200 further includes a first driving circuit 211 located in the transition region 22, and the first driving circuit 211 is provided with a first output end 212.

The driving backboard 200 further includes: a second driving circuit located in the transition region 22, and the second driving circuit is provided with a second output end; a third driving circuit 213 located in the main screen region 23, and the third driving circuit 213 is provided with a third output end 214.

In step S2, referring to FIG. 8, a first planarization layer 221 is formed on the driving backboard 200 of the main screen region 23, the transition region 22 and the light-transmitting region 21; a first through hole is formed in the first planarization layer 221 of the transition region 22, and the surface of the first output end 212 is exposed by the first through hole.

In step S3, referring to FIG. 9, a first electrode layer 222 is formed on a surface of the first planarization layer 221 of the transition region 22, the surface of the first planarization layer 221 of the transition region 22 is away from the driving backboard 200, and the first electrode layer 222 also covers the bottom and sidewalls of the first through hole.

In this embodiment, in the process step of forming the first electrode layer 222, a plurality of discrete light-reflecting layers 223 on the first planarization layer 221 of the light-transmitting region 21 are also formed.

In this embodiment, the first electrode layer 222 includes a first transparent electrode layer, a metal electrode layer, and a second transparent electrode layer which are sequentially stacked. Herein, a material of the first transparent electrode layer is ITO, and its thickness is 80 Å˜120 Å, such as 90 Å, 100 Å, and 110 Å; a material of the second transparent electrode layer is ITO, and its thickness is 80 Å˜120 Å, such as 90 Å, 100 Å, 110 Å; a material of the metal electrode layer is Ag or Mg, and its thickness is 900 Å to 1100 Å, such as 950 Å, 1000 Å, or 1050 Å.

In this embodiment, in the process step of forming the first electrode layer 222, the third electrode layer 301 located on the first planarization layer 221 of the transition region 22 and the fifth electrode layer 303 located on the first planarization layer 221 of the main screen region 23 are also formed.

The process steps of forming the first electrode layer 222, the light-reflecting layer 223, the third electrode layer 301 and the fifth electrode layer 303 include: forming a first electrode film on the surface of the first planarization layer 221, and the first electrode film also covers the bottom and sidewalls of the first through hole; patterning the first electrode film by a wet etching process to form the first electrode layer 222, the third electrode layer 301, the fifth electrode layer 303 and the light-reflecting layer 223.

The etching liquid used in the wet etching process may be an acid solution containing HNO₃, CH₃COOH, and H₃PO₄.

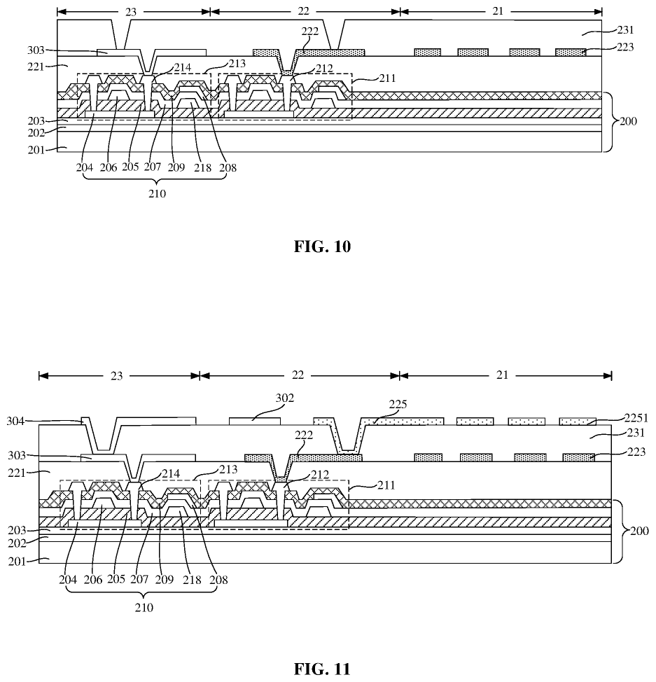

In step S4, referring to FIG. 10, a second planarization layer 231 is formed on the first planarization layer 221, the first electrode layer 222, the light-reflecting layer 223, the third electrode layer 301, and the fifth electrode layer 303; a second through hole exposing the first electrode layer 222 is formed in the second planarization layer 231 of the transition region 22; a fifth through hole exposing the third electrode layer 301 is formed in the second planarization layer 231 of the transition region 22; a sixth through hole exposing the fifth electrode layer 303 is formed in the second planarization layer 231 of the main screen region 23.

In step S5, referring to FIG. 11, a second electrode layer 225 is formed on the surface of the second planarization layer 231 of the light-transmitting region 21 and the transition region 22, the surface of the second planarization layer 231 of the light-transmitting region 21 and the transition region 22 is away from the driving backboard 200, and the second electrode layer 225 is also located at the bottom and sidewalls of the second through hole.

The material of the second electrode layer 225 is ITO or IZO.

In this embodiment, in the process step of forming the second electrode layer 225, a fourth electrode layer 302 located in the transition region 22 is also formed, the fourth electrode layer 302 covers the bottom and sidewalls of the fifth through hole. A sixth electrode layer 304 located in the main screen region 23 is also formed, and the sixth electrode layer 304 covers the bottom and sidewalls of the sixth through hole. That is, the second electrode layer 225, the fourth electrode layer 302, and the sixth electrode layer 304 are made of the same material.

The process steps for forming the second electrode layer 225, the fourth electrode layer 302 and the sixth electrode layer 304 include: forming a second electrode film on the second planarization layer 231, and the second electrode film also covers the bottom and sidewalls of the second through hole, the bottom and sidewalls of the fifth through hole, and the bottom and sidewalls of the sixth through hole; patterning the second electrode film by a wet etching process to form the second electrode layer 225, the fourth electrode layer 302, and the sixth electrode layer 304.

In this embodiment, a sputtering process is used to form the second electrode film, and the etching liquid used in the wet etching process may be oxalic acid.

In step S6, referring to FIG. 4, a plurality of first light-emitting units 224 located in the light-transmitting region 21 is formed, and the second electrode layer 225 is used for providing electrical signals for the plurality of first light-emitting units 224; a second light-emitting unit 228 located in the transition region 22 is formed, and the fourth electrode layer 302 is used for providing an electrical signal for the second light-emitting unit 228; the third light-emitting unit 230 located in the main screen region 23 is formed, and the sixth electrode layer 304 is used for providing an electrical signal for the third light-emitting unit 230.

Before forming the first light emitting unit 224, the second light emitting unit 228 and the third light emitting unit 230, the method further includes: forming a pixel defining layer 240 on the second planarization layer 231.

The subsequent process steps further include: forming a supporting portion 241 on the pixel defining layer 240; forming a cathode 226 on the first light-emitting units 224, the second light-emitting unit 228, and the third light-emitting unit 230.

The method for manufacturing the display panel provided in this embodiment only uses a single-layer transparent electrode layer, that is, the second electrode layer 225, to wiring for the anode of the light-transmitting region 21, which saves ITO productive capacity and avoids the adverse effects caused by the ITO manufacturing process on the first planarization layer 221 of the transition region 22 and the main screen region 23. Therefore, the Ag migration problem on the first planarization layer 221 of the transition region 22 and the main screen region 23 can be avoided, and further the abnormality problem of the product caused by the Ag migration problem can be avoided.

In addition, since the first electrode layer 221 is prepared firstly and then the second electrode layer 225 is prepared, the damage to the first planarization layer 221 caused by the ITO process may be avoided. As a result, the Ag migration problem of the first electrode layer 221 located on the first planarization layer 221 can be avoided.

In addition, this embodiment can avoid the damage to the second output end and the third output end 213 caused by the ITO process, thereby avoiding the abnormal overlap between the main screen region electrode of the main screen region 23 and the third output end 213, and avoiding the abnormal overlap between the transition region electrode of the transition region 22 and the second output end.

At the same time, the method provided in this embodiment is conducive to saving process steps, reducing manufacturing costs, and ensuring the uniformity of the cavity length of the optical microcavity of the light-transmitting region 21, the transition region 22, and the main screen region 23, thereby improving the display effect of the display panel.

It shall be understand that, in other embodiments, the third electrode, the fourth electrode, the fifth electrode, and the sixth electrode may not be formed. The steps of forming the transition region electrode and the main screen region electrode include: after forming the second planarization layer, forming a third through hole in the second planarization layer and the first planarization layer of the transition region, and the third through hole exposes the second output end of the second driving circuit; forming a fourth through hole in the second planarization layer and the first planarization layer of the main screen region, the fourth through hole exposes the third output end of the third driving circuit; forming a transition region electrode on the second planarization layer and on the bottom and sidewalls of the third through hole; forming a main screen region electrode on the second planarization layer and the bottom and sidewalls of the fourth through hole.

In some embodiments of the present disclosure, the planarization layer includes a first planarization layer and a second planarization layer which are sequentially stacked, and the electrode for electrically connecting the first driving circuit and the first light-emitting units include: the first electrode layer between the first planarization layer and the second planarization layer, and the first electrode layer is located in the transition region; the second electrode layer located on the surface of the second planarization layer, and the second electrode layer is located in the transition region and the light-transmitting region. Since the first electrode layer is located in the transition region, there is no need to consider the influence of the first electrode layer on the light transmittance of the light-transmitting region. Therefore, the first electrode layer may be a laminated conductive material, that is, there is no need to provide a transparent conductive material at a side of the first planarization layer, the side of the first planarization layer faces to the driving backboard, which may avoid the adverse effects of the manufacturing process of the transparent conductive material (such as ITO) and improve the performance of the display panel. Some of the embodiments of the present disclosure can avoid damage to the second output end of the transition region caused by the process of forming the transparent conductive layer by the sputtering bombardment process, thereby avoiding the problem of abnormal electrical connection and improving the display performance of the display panel.

Those skilled in the art shall understand that the above-mentioned embodiments are specific embodiments for realizing the present disclosure, and in actual applications, various changes can be made in form and details without departing from the spirit and scope of the present disclosure. Any person skilled in the art can make their own changes and modifications without departing from the spirit and scope of the present disclosure. Therefore, the protection scope of the present disclosure shall be subject to the scope defined by the claims.

What is claimed is:

1. A display panel, comprising a transition region and a light-transmitting region, wherein a light transmittance of the light-transmitting region is greater than a light transmittance of the transition region; and
the display panel further comprises:
a driving backboard comprising a first driving circuit located in the transition region, and the first driving circuit having a first output end;
a first planarization layer located on the driving backboard of the transition region and the light-transmitting region;
a first electrode layer located at a side of the first planarization layer of the transition region, the side of the first planarization layer of the transition region being away from the driving backboard, and the first electrode layer extending through the first planarization layer to electrically connect with the first output end;
a second planarization layer located at a side of the first planarization layer and the first electrode layer, the side of the first planarization layer and the first electrode layer being away from the driving backboard;
a second electrode layer located at a side of the second planarization layer of the transition region and the light-transmitting region, the side of the second planarization layer of the transition region and the light-transmitting region being away from the driving backboard, and the second electrode layer extending through the second planarization layer to contact with the first electrode layer.

2. The display panel according to claim 1, further comprising a plurality of first light-emitting units in the light-transmitting region, wherein the first light-emitting units are located at a side of the second electrode layer, the side of the second electrode layer is away from the driving backboard, and the second electrode layer is used for providing an electrical signal for the first light-emitting unit.

3. The display panel according to claim 1, wherein a light transmittance of the second electrode layer is greater than or equal to a light transmittance of the first electrode layer.

4. The display panel according to claim 2, wherein the second electrode layer located in the light-transmitting region comprises a plurality of electrode blocks and a plurality of electrode bridges for connecting adjacent electrode blocks, and each of the first light-emitting units is correspondingly located at a side of each of the electrode blocks, the side of each of the electrode blocks is away from the driving backboard.

5. The display panel according to claim 4, wherein the second electrode layer of the light-transmitting region has a wave shape, and each of the electrode blocks is located at a peak of the wave shape or a trough of the wave shape.

6. The display panel according to claim 1, wherein a material of the second electrode layer is a transparent conductive material.

7. The display panel according to claim 1, wherein the first electrode layer comprises a first transparent electrode layer, a metal electrode layer and a second transparent electrode layer which are sequentially stacked.

8. The display panel according to claim 2, further comprising a plurality of discrete light-reflecting layers, wherein the light-reflecting layers are located at a side of the first planarization layer of the light-transmitting region, the side of the first planarization layer of the light-transmitting region is away from the driving backboard, and each of the light-reflecting layers corresponds to a position of each of the first light-emitting units.

9. The display panel according to claim 8, wherein an orthographic projection of each of the light-reflecting layers on the driving backboard is located in an orthographic projection of each of the first light-emitting units on the driving backboard.

10. The display panel according to claim 8, wherein the light-reflecting layers and the first electrode layer are provided in the same layer, and a material of the light-reflecting layers is the same as a material of the first electrode layer.

11. The display panel according to claim 1, wherein the driving backboard comprises a second driving circuit located in the transition region, and the second driving circuit has a second output end, and the display panel further comprises:
a transition region electrode located at a side of the second planarization layer of the transition region, the side of the second planarization layer of the transition region being away from the driving backboard, and the transition region electrode extending through the first planarization layer and the second planarization layer to electrically connect with the second output end; and
a second light-emitting unit in the transition region, the second light-emitting unit being located at a side of the transition region electrode, the side of the transition region electrode being away from the driving backboard, and the transition region electrode being used for providing an electrical signal for the second light-emitting unit.

12. The display panel according to claim 1, wherein the driving backboard comprises a second driving circuit located in the transition region, and the second driving circuit has a second output end, and the display panel further comprises a transition region electrode, and the transition region electrode comprises:
a third electrode layer located at a side of the first planarization layer, the side of the first planarization layer being away from the driving backboard, and the third electrode layer extending through the first planarization layer to contact with the second output end;
a fourth electrode layer located at a side of the second planarization layer, the side of the second planarization layer being away from the driving backboard, and the fourth electrode layer extending through the second planarization layer to contact with the third electrode layer; and
a second light-emitting unit in the transition region, the second light-emitting unit being located at a side of the transition region electrode, the side of the transition region electrode being away from the driving backboard, and the transition region electrode being used for providing an electrical signal for the second light-emitting unit.

13. The display panel according to claim 12, wherein the third electrode layer and the first electrode layer are provided in the same layer, and a material of the third electrode layer is same as a material of the first electrode layer; the fourth electrode layer and the second electrode layer are provided in the same layer, and a material of the fourth electrode layer is same as a material of the second electrode layer.

14. The display panel according to claim 1, wherein the display panel further comprises a main screen region, and the transition region is located between the main screen region and the light-transmitting region; the driving backboard further comprises a third driving circuit located in the main screen region, and the third driving circuit comprises a third output end;
wherein the display panel further comprises:
a main screen region electrode located at a side of the second planarization layer of the main screen region, the side of the second planarization layer of the main screen region being away from the driving backboard, and the main screen region electrode extending through the first planarization layer and the second planarization layer to electrically connect with the third output end; and,
a third light-emitting unit disposed in the main screen region, the third light-emitting unit being located at a side of the main screen region electrode, the side of the main screen region electrode being away from the driving backboard, and the main screen region electrode being used for providing an electrical signal for the third light-emitting unit.

15. The display panel according to claim 1, wherein the display panel further comprises a main screen region, and the transition region is located between the main screen region and the light-transmitting region; the driving backboard further comprises a third driving circuit located in the main screen region, and the third driving circuit comprises a third output end;
wherein the display panel further comprises:
a main screen region electrode comprising:
a fifth electrode layer located at a side of the first planarization layer, the side of the first planarization layer being away from the driving backboard, and the fifth electrode layer extending through the first planarization layer to contact with the third output end; and
a sixth electrode layer located at a side of the second planarization layer, the side of the second planarization layer being away from the driving backboard, and the sixth electrode layer extending through the second planarization layer to contact with the fifth electrode layer; and
a third light-emitting unit disposed in the main screen region, the third light-emitting unit being located at a side of the main screen region electrode, the side of the main screen region electrode being away from the driving backboard, and the main screen region electrode being used for providing an electrical signal for the third light-emitting unit.

16. The display panel according to claim 15, wherein the fifth electrode layer and the first electrode layer are provided in the same layer, and a material of the fifth electrode layer is same as a material of the first electrode layer; the sixth electrode layer and the second electrode layer are provided in the same layer, and a material of the sixth electrode layer is same as a material of the second electrode layer.

17. A display device, comprising the display panel according to claim 1.
